(19) United States
(12) Patent Application Publication
(10) Pub. No.: US 2007/0183208 A1
(43) Pub. Date: Aug. 9, 2007

(54) Nonvolatile semiconductor memory device and data writing method therefor

(76) Inventors: Masayuki Tanaka, Yokohama-shi (JP); Ryota Fujitsuka, Yokohama-shi (JP); Katsuyuki Sekine, Yokohama-shi (JP); Yoshio Ozawa, Yokohama-shi (JP); Daisuke Nishida, Yokohama-shi (JP)

Correspondence Address: FINNEGAN, HENDERSON, FARABOW, GARRETT & DUNNER;LLP, 901 NEW YORK AVENUE, NW, WASHINGTON, DC, 20001-4413, US

(21) Appl. No.: 11/653,278

(22) Filed: Jan. 16, 2007

(30) Foreign Application Priority Data
Jan. 17, 2006 (JP) 2006-009032

(51) Int. Cl. G11C 11/34; G11C 16/04; G11C 16/06

(52) U.S. Cl. 365/185.22; 365/185.02; 365/185.05; 365/185.24

(57) ABSTRACT

A plurality of memory cell transistors each of which has a gate structure having a floating gate electrode formed of a first conductive film and stacked on an element region surrounded by an element isolation region on a silicon substrate with a first insulating film disposed therebetween and a control gate electrode formed of a second conductive film and stacked on the first conductive film with a second insulating film with a large dielectric constant disposed therebetween are arranged in a memory cell array. A detrap pulse supply circuit generates and supplies a detrap pulse signal to the control gate electrode of the memory cell transistor to extract charges from the second insulating film after data is written into each of the memory cell transistors.

### CROSS-REFERENCE TO RELATED APPLICATIONS

This application is based upon and claims the benefit of priority from prior Japanese Patent Application No. 2006-009032, filed Jan. 17, 2006, the entire contents of which are incorporated herein by reference.

### BACKGROUND OF THE INVENTION

1. Field of the Invention

This invention relates to a nonvolatile semiconductor memory device including memory cells which include transistors each having the stacked gate structure including a floating gate electrode and control gate electrode and each hold data by trapping charges in the floating gate electrode after a data writing process.

2. Description of the Related Art

In a next-generation nonvolatile semiconductor memory device, the distance between nonvolatile memory cells (which are hereinafter referred to as memory cells) is reduced and, as a result, the effect of interference between the adjacent memory cells due to capacitive coupling increases. An increase in the interference effect significantly deteriorates the memory cell characteristics. Therefore, it is strongly required to reduce the degree of the interference effect. In order to reduce the degree of the interference effect, it is preferable to reduce the capacitance of the parasitic capacitor parasitically occurring between the memory cells. One method of reducing the capacitance of the parasitic capacitor is to reduce the facing areas of the floating gate electrodes of the adjacent memory cells by reducing the heights of the floating gate electrodes of the transistors of the stacked gate structures configuring the memory cells.

The height of the floating gate electrode is determined to set the capacitance ratio of the capacitance between the control gate electrode and the floating gate electrode of the memory cell transistor to the capacitance between the floating gate electrode and the substrate to a desired value. Therefore, the height of the floating gate electrode can be reduced by reducing the thickness of an inter-layer insulating film between the control gate electrode and the floating gate electrode to increase the capacitance between the gates. For example, the inter-layer insulating film can be made thin by using an insulating film with a relative high dielectric constant (which is hereinafter referred to as high-k film) and an increase in the degree of the interference effect caused by reducing the memory cell size can be suppressed.

However, the inventors of this application found a problem that the high-k film trapped a large amount of charges and charges were trapped in the inter-layer insulating film after the write/erase operation was performed with respect to the memory cell transistor and discharged again at the charge holding time to change the threshold voltage of the memory cell transistor.

In the U.S. Pat. Specification No. 5,883,835 by Kodama, a control method for a nonvolatile memory which prevents deterioration in the data memory characteristic is disclosed. Further, in the U.S. Pat. Specification No. 6,567,312 by Torii e al, a nonvolatile memory which improves the data read characteristic of a SONOS type memory cell is disclosed. In Jpn. Pat. Appln. KOKAI Publication No. 2001-325793, the technique for enhancing the writing reliability of a single-gate type nonvolatile memory cell transistor which traps charges in a gate insulating film capable of storing charges.

### BRIEF SUMMARY OF THE INVENTION

According to a first aspect of the invention, there is provided a nonvolatile semiconductor memory device comprising a memory cell array in which a plurality of data writable memory cells each having a floating gate electrode stacked on an element region surrounded by an element isolation region on a semiconductor substrate with a first insulating film disposed therebetween and a control gate electrode stacked on the floating gate electrode with a second insulating film disposed therebetween are arranged, and a detrap pulse supply circuit which is connected to the memory cell array and supplies a detrap pulse signal to the control gate electrode of each of the memory cells to extract charges from the second insulating film after data is written into each of the plurality of memory cells.

According to a second aspect of the invention, there is provided a data writing method of writing data with respect to data writable memory cell transistors each of which has a floating gate electrode stacked on a semiconductor substrate with a first insulating film disposed therebetween and a control gate electrode stacked on the floating gate electrode with a second insulating film disposed therebetween, comprising supplying write voltage to the control gate electrode to write data into the memory cell, reading out data from the memory cell subjected to the write process and verifying a write state, and supplying a detrap pulse signal to the control gate electrode to extract charges from the second insulating film after it is verified that data has been written into the memory cell.

### BRIEF DESCRIPTION OF THE SEVERAL VIEWS OF THE DRAWING

FIG. 1 is a block diagram of a NAND flash memory according to one embodiment of the invention,

FIG. 2 is a pattern plan view of part of a memory cell array shown in FIG. 1,

FIG. 3 is an equivalent circuit diagram of the memory cell array shown in FIG. 2,

FIG. 4 is a cross sectional view taken along the IV-IV line of FIG. 2,

FIG. 5 is a cross sectional view taken along the V-V line of FIG. 2,

FIG. 6 is a waveform diagram showing one example of a case wherein a write pulse and detrap pulse are applied when data is written into memory cell transistors of the flash memory of FIG. 1,

FIG. 7 is a characteristic diagram showing the data retention characteristic of the memory cell transistor,

FIG. 8 is a characteristic diagram showing the measurement result of a gate voltage-capacitance characteristic of an MIS capacitor, and

FIG. 9 is a flowchart showing one example of the write operation of the flash memory of FIG. 1.

### DETAILED DESCRIPTION OF THE INVENTION

There will now be described an embodiment of the invention with reference to the accompanying drawings. In the explanation, the same reference symbols are attached to portions which are the same throughout the whole drawings.

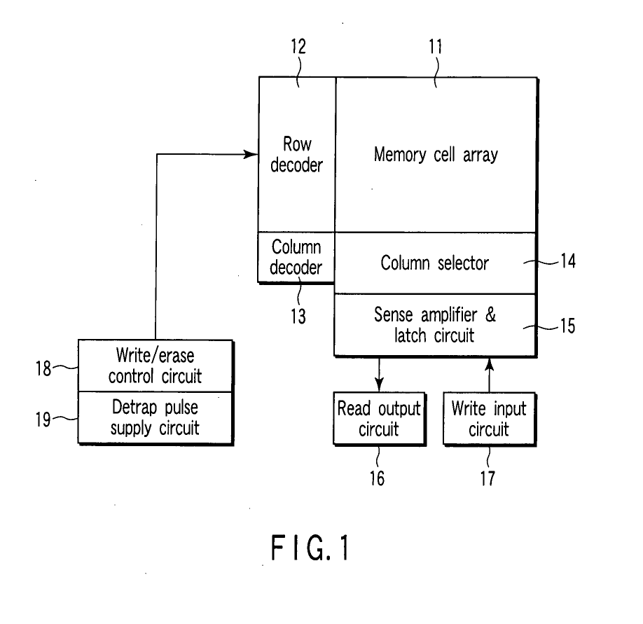

FIG. 1 is a block diagram of a NAND flash memory according to one embodiment of the invention. A reference symbol 11 denotes a memory cell array, 12 a row decoder, 13 a column decoder, 14 a column selector, 15 a sense amplifier & latch circuit, 16 a read output circuit, 17 a write input circuit, and 18 a write/erase control circuit which generates a desired pulse signal and write/erase voltage according to the operation mode.

The memory cell array 11 has the same configuration as the known memory cell array and is configured by arranging a plurality of memory cell transistors each having a double-gate structure formed on an element region surrounded by an element isolation region in a memory cell array region on a semiconductor substrate. Each of the memory cell transistors has the same structure as the known memory cell transistor and a floating gate electrode formed of a first conductive film is stacked on the semiconductor substrate with a first insulating film disposed therebetween and a control gate electrode formed of a second conductive film is stacked on the floating gate electrode with a second insulating film disposed therebetween. In this example, a high-k film with a relative dielectric constant of approximately 5 or more is used as the second insulating film.

In the present embodiment, there is provided a detrap pulse supply circuit 19 which generates and supplies a detrap pulse signal to the memory cell in order to extract charges from the second insulating film after data is written into the memory cell. The detrap pulse supply circuit 19 can be provided in the write/erase control circuit 18.

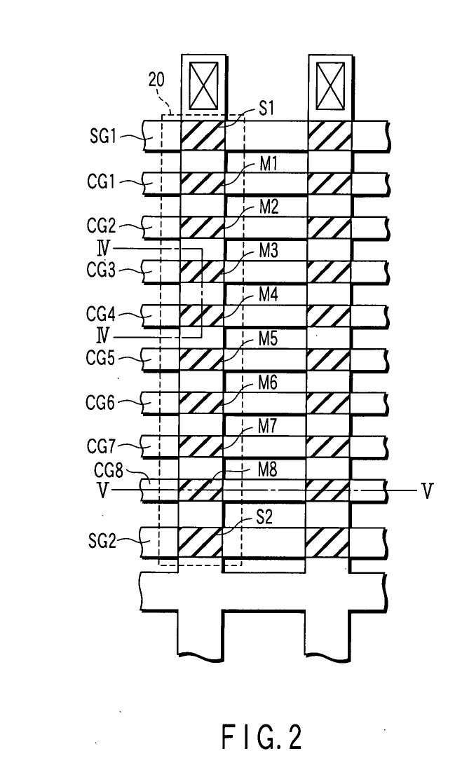

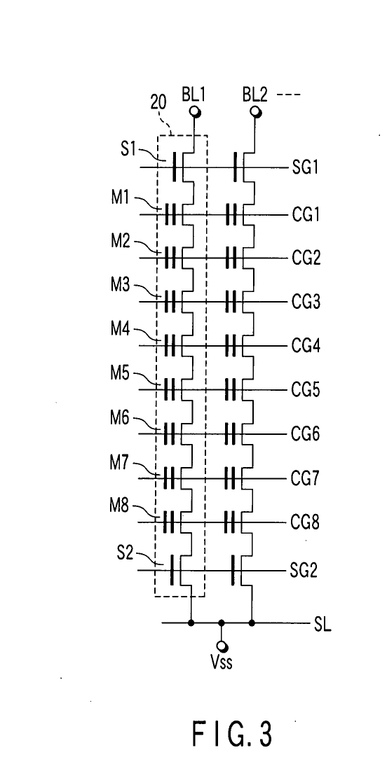

FIG. 2 is a pattern plan view of part of the memory cell array 11 shown in FIG. 1. For clear understanding, bit lines are omitted in FIG. 2. FIG. 3 is an equivalent circuit diagram of the memory cell array shown in FIG. 2.

In the memory cell array shown in FIGS. 2 and 3, each of NAND cell units 20 includes a plurality of memory cell transistors M1 to M8 serially connected, and selection transistors S1, S2 arranged on both end sides of the series circuit of the memory cell transistors. The gate electrodes of the selection transistors S1, S2 are respectively connected to selection gate lines SG1, SG2. The control gate electrodes of the memory cell transistors M1 to M8 are respectively connected to word lines CG1 to CG8. Further, the drains of the selection transistors S1 of the NAND cell units 20 are respectively connected to bit lines BL1, BL2, . . . . The sources of the selection transistors S2 are commonly connected a source line SL. In this example, a case wherein eight memory cell transistors are serially connected in each NAND cell unit 20 is shown. However, the number of memory cells is not limited to eight and can be set to 16 or 32, for example.

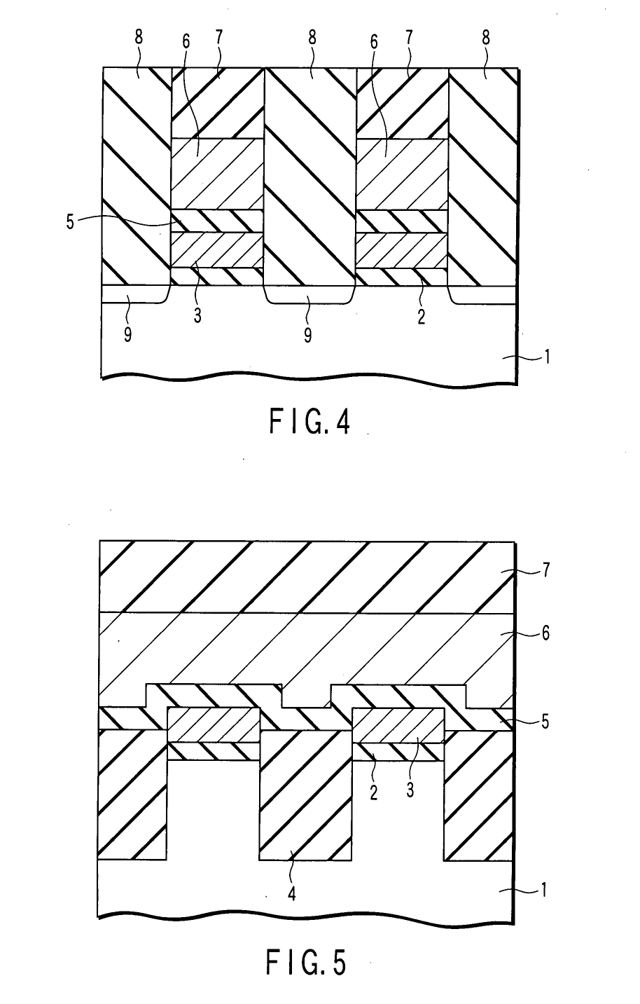

FIG. 4 is a cross sectional view of the memory cell transistors taken along the IV-IV line of FIG. 2 and FIG. 5 is a cross sectional view taken along the V-V line of FIG. 2. As shown in FIGS. 4 and 5, for example, the memory cell transistors M1 to M8 are formed on a p-type silicon substrate 1. That is, each of the memory cell transistors M1 to M8 has a double-gate structure having source/drain regions 9 formed on the silicon substrate 1, a first insulating film (tunnel insulating film) 2 formed on the channel region between the source/drain regions 9, a floating gate electrode 3 formed of a first conductive film on the first insulating film 2, a second insulating film (inter-layer insulating film) 5 having a dielectric constant larger than that of a silicon oxide film and formed on the floating gate electrode 3, and a control gate electrode 6 formed of a second conductive film such as a polysilicon film on the second insulating film 5. In this case, the adjacent NAND cell units are isolated from each other by use of a trench type element isolation region (STI) 4. The second insulating film 5 and control gate electrode 6 are formed to extend in a direction parallel to a direction in which word lines of the memory cell array region extend on the exposed upper surfaces of both of the element isolation region 4 and floating gate electrode 3. A reference symbol 7 denotes a mask member, the memory cell transistors, selection transistors and the like are covered with an interlayer insulating film 8 and bit lines (not shown) are formed on the interlayer insulating film 8.

When a high-k film is used as the second insulating film (inter-layer insulating film) 5, the withstand voltage of the insulating film itself becomes high and a leak current can be reduced even when a high electric field is applied thereto at the write time. Therefore, as the second insulating film, an insulating film with a dielectric constant larger than that of a silicon oxide film is used. As the second insulating film 5, an insulating film with a dielectric constant larger than the dielectric constant (3.8 to 4.0) of a silicon oxide film and larger than the dielectric constant of approximately 5.0 to 5.5 of an ONO film used as the inter-layer insulating film can be used. For example, an insulating film containing hafnium (Hf) or aluminum (Al) as a component can be used. As a concrete example, a silicon nitride (Si₃N₄) film with a relative dielectric constant of approximately 7, an aluminum oxide (Al₂O₃) film with a relative dielectric constant of approximately 8 or more, a hafnium oxide (HfO₂) film or zirconium oxide (ZrO₂) film with a relative dielectric constant of approximately 22, or a lanthanum oxide (La₂O₃) film with a relative dielectric constant of approximately 25 can be used. Further, an insulating film formed of a ternary compound such as a hafnium silicate (HfSiO) film, hafnium aluminate (HfAlO) film, lanthanum aluminate (LaAlO) film or zirconium aluminate (ZrAlO) film can be used.

In addition, as the second insulating film 5, an insulating film with the structure formed by laminating a plurality of films containing at least two of a silicon oxide, silicon nitride and hafnium oxide can be used. For example, an insulating film with the structure obtained by sandwiching an HfSiO film between silicon nitride films, the structure obtained by sandwiching an HfSiO film between silicon oxide films or the structure obtained by forming silicon nitride films on the upper and lower surfaces of the above structure can be used.

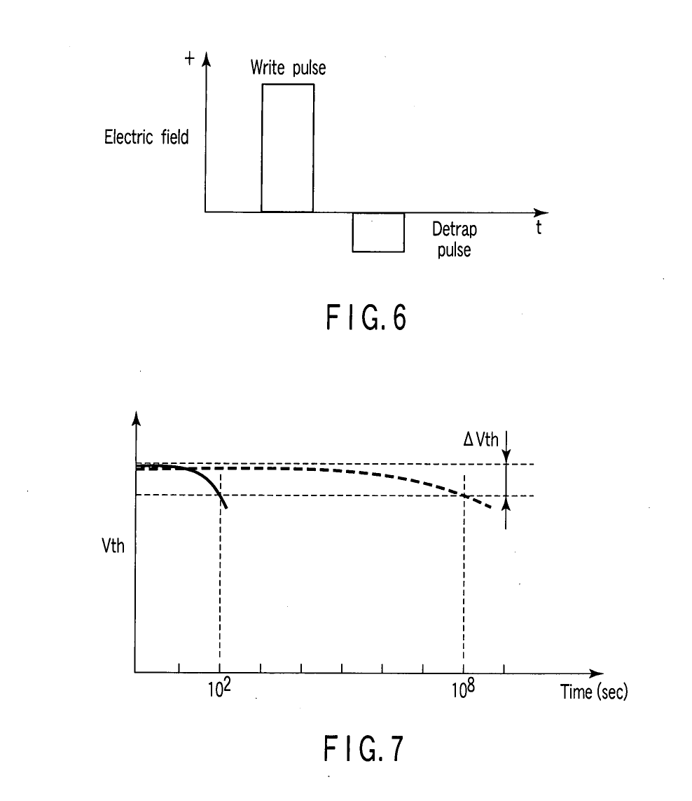

FIG. 6 is a waveform diagram showing one example of a case wherein a write pulse signal and detrap pulse signal are supplied to a memory cell transistor when data is written into the memory cell transistor in the memory cell array 11 of FIG. 1. In the data write operation, write voltage with a positive polarity is applied to the control gate electrode 6 of the memory cell transistor to inject electrons into the floating gate electrode 3 via the first insulating film (tunnel insulating film) 2 from the silicon substrate 1. In this case, the value of the write voltage is adjusted to set an electric field applied to the first insulating film 2 to approximately 25 MV/cm or less at maximum. Further, time during which the write voltage is applied is set in a range from 1 microsecond to 10 milliseconds. Since an intense electric field is applied to the second insulating film (inter-layer insulating film) 5 at the data write operation, part of the electrons injected into the floating gate electrode 3 is injected into the second insulating film 5 and part of the injected electrons passes or tunnels therethrough to the control gate electrode 6. At this time, since charge traps are present in the second insulating film 5, part of the injected electrons is trapped in the second insulating film 5.

FIG. 7 shows one example of a data retention characteristic (indicated by broken lines) when an ONO film is used as the inter-layer insulating film of the memory cell transistor and a data retention characteristic (indicated by a solid line) when an insulating film having a dielectric constant larger than that of an ONO film is used. As shown in FIG. 7, when an insulating film having a dielectric constant larger than that of an ONO film is used, electrons trapped in the inter-layer insulating film in the write operation are detrapped and, as a result, time required for changing the threshold voltage of the memory cell transistor by a preset variation amount (ΔVth) will be reduced and the data retention characteristic will be deteriorated earlier than usual.

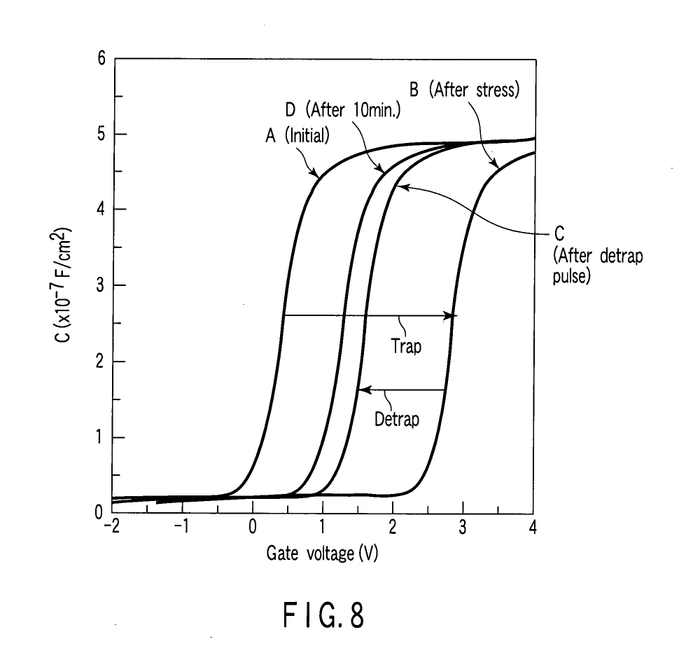

FIG. 8 shows the measurement result of a gate voltage-capacitance characteristic (CV curve) of a metal-insulator-semiconductor (MIS) capacitor having a high-k film formed on the semiconductor substrate. In this case, the characteristic A indicates a CV curve in the initial state (“Initial”), the characteristic B indicates a CV curve obtained after electric field stress corresponding to write voltage is applied (“After stress”) and the characteristic D indicates a CV curve measured after the device is further allowed to stand for 10 minutes (“After 10 min”), for example. Electrons are trapped (“Trap”) in the high-k film by applying the electric field stress corresponding to the write voltage and, as a result, the CV curve is shifted in a positive voltage direction from the characteristic A to the characteristic B. When the device is allowed to stand for 10 minutes at the charge holding stage after the end of the write process, that is, after the write electric field is eliminated, the electrons trapped in the high-k film as described before pass or tunnel therethrough to the floating gate electrode side or control gate electrode side with time and the CV curve is shifted in a negative voltage direction from the characteristic B to the characteristic D. A variation amount ΔVth of the threshold voltage of the memory cell transistor caused by extracting the electrons is large and cannot be tolerated from the viewpoint of the characteristic of the flash memory.

Therefore, in the present embodiment, the detrap pulse supply circuit 19 is provided as shown in FIG. 1 and a detrap step of supplying a detrap pulse signal generated by the detrap pulse supply circuit 19 to the control gate electrode to forcedly extract the trapped electrons from the second insulating film (inter-layer insulating film) 5 after elimination of the write electric field is additionally provided as shown in FIG. 6. The detrap pulse signal is supplied to the control gate electrode of the memory cell transistor to set the maximum value of the absolute value of the electric field applied to the second insulating film (inter-layer insulating film) 5 to 25 MV/cm and set the pulse width in a range from 0.1 microsecond to 10 milliseconds. A case wherein an electric field applied to the second insulating film by supplying the detrap pulse signal is positive corresponds to extraction of electrons to the control gate electrode side and a case wherein the electric field is negative corresponds to extraction of electrons to the floating gate electrode side. For example, FIG. 6 shows a case wherein a negative electric field is applied to the second insulating film 5 by supplying the detrap pulse signal. However, it is possible to supply a detrap pulse signal to the control gate electrode so as to apply a positive electric field to the second insulating film 5.

The characteristic C in the CV curve of FIG. 8 corresponds to the measurement result of the CV curve after the detrap pulse signal is supplied as shown in FIG. 6. That is, in the present embodiment, electrons in the second insulating film are extracted and Vfb is shifted (from the characteristic B to the characteristic C in the CV curve) by supplying the detrap pulse signal after Vfb is shifted (from the characteristic A to the characteristic B in the CV curve) due to the write electric field stress. As a result, the Vfb shifting value (from the characteristic B to the characteristic C) can be made smaller than a shift value (from the characteristic B to the characteristic D) caused when the detrap pulse signal is not supplied.

When the detrap pulse signal is supplied, it is necessary to carefully set the electric field (voltage value) and pulse width so as not to cause a state in which a large amount of electrons in the floating gate electrode are extracted or a large amount of holes are injected to prevent occurrence of a data writing/erasing operation. As described before, the voltage value is selected to set the maximum value of the absolute value of the electric field applied to the second insulating film (inter-layer insulating film) 5 to 25 MV/cm and the pulse width is selected to be set in a range from 0.1 microsecond to 10 milliseconds.

As described above, in the present embodiment, electrons trapped in the inter-layer insulating film of the memory cell transistor are extracted in the write operation by supplying a short pulse signal to the memory cell transistor after data is written into the memory cell transistor having the double-gate structure. As a result, deterioration in the memory cell characteristic by detrapping the electrons which causes a problem when a high-k film is used as the inter-layer insulating film of the memory cell transistor can be suppressed and thus the data retention characteristic can be improved.

The above-described effect is effective particularly when a high-k film is used as the inter-layer insulating film. However, when an ONO film is used as the inter-layer insulating film, it is effective to perform the same operation as in the present embodiment if deterioration in the data retention characteristic of the memory cell transistor by detrapping is significant.

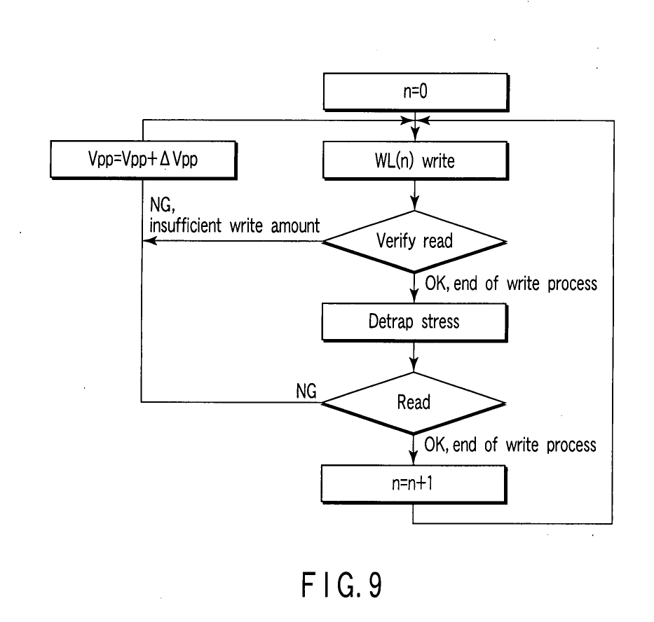

FIG. 9 is a flowchart showing one example of the data write operation when a verify write operation with respect to the memory cell transistor of the present embodiment is performed. When data is written into the memory cell transistor whose control gate electrode is connected to a specified word line WL(n), write voltage Vpp is applied to the word line to write data into the memory cell transistor. Then, a verify read operation is performed with respect to the memory cell transistor into which data is written. As the verify result, the threshold voltage of the memory cell transistor has reached a desired value and when it is ensured that the write operation is performed, a detrap pulse signal is supplied to apply detrap pulse stress to the memory cell transistor. Next, data is read out from the memory cell transistor to determine whether or not the write operation is performed to attain desired threshold voltage. When the write operation is performed, the write operation is terminated, the word line is changed to a next word line (n=n+1) and the verify write operation which is the same as the former case is performed. When the threshold voltage of the memory cell transistor does not reach the desired value, the write voltage is increased (Vpp=Vpp+ΔVpp), the write operation is performed again and the write operation is repeatedly performed until the threshold voltage reaches the desired value after the detrap pulse signal is supplied.

Additional advantages and modifications will readily occur to those skilled in the art. Therefore, the invention in its broader aspects is not limited to the specific details and representative embodiments shown and described herein. Accordingly, various modifications may be made without departing from the spirit or scope of the general inventive concept as defined by the appended claims and their equivalents. For example, in the above present embodiment, a case wherein the invention is applied to the NAND flash memory is explained, but the invention can be generally applied to a nonvolatile semiconductor memory device other than the NAND flash memory.

What is claimed is:

1. A nonvolatile semiconductor memory device comprising:
a memory cell array which has a plurality of data writable memory cells arranged therein, each memory cell having a floating gate electrode stacked on an element region surrounded by an element isolation region on a semiconductor substrate with a first insulating film disposed therebetween and a control gate electrode stacked on the floating gate electrode with a second insulating film disposed therebetween; and
a detrap pulse supply circuit which is connected to the memory cell array and supplies a detrap pulse signal to the control gate electrode of each of the plurality of memory cells after data is written into each of the memory cells to extract charges from the second insulating film.

2. The nonvolatile semiconductor memory device according to claim 1, wherein the detrap pulse supply circuit supplies a pulse signal having pulse width in a range of 0.1 microsecond to 10 milliseconds as the detrap pulse signal to the control gate electrode.

3. The nonvolatile semiconductor memory device according to claim 1, wherein the detrap pulse supply circuit supplies the detrap pulse signal having a voltage value which causes an electric field applied to the second insulating film to be set to 25 MV/cm at maximum to the control gate electrode.

4. The nonvolatile semiconductor memory device according to claim 1, wherein the detrap pulse supply circuit supplies the detrap pulse signal to the control gate electrode after a verify write operation when a process of writing data into the memory cell is performed by the verify write operation.

5. The nonvolatile semiconductor memory device according to claim 4, wherein the detrap pulse supply circuit supplies the detrap pulse signal having a polarity which causes electrons trapped in the second insulating film to be extracted from one of the control gate electrode and floating gate electrode to the control gate electrode.

6. The nonvolatile semiconductor memory device according to claim 1, wherein the second insulating film is an insulating film having a relative dielectric constant larger than 5.0 to 5.5.

7. The nonvolatile semiconductor memory device according to claim 6, wherein the insulating film is an insulating film containing one of hafnium (Hf) and aluminum (Al).

8. The nonvolatile semiconductor memory device according to claim 6, wherein the insulating film is an insulating film which is one selected from a group consisting of a silicon nitride (Si₃N₄) film, aluminum oxide (Al₂O₃) film, hafnium oxide (HfO₂) film, zirconium oxide (ZrO₂) film and lanthanum oxide (La₂O₃) film.

9. The nonvolatile semiconductor memory device according to claim 6, wherein the insulating film is an insulating film containing a ternary compound which is one selected from a group consisting of a hafnium silicate (HfSiO) film, hafnium aluminate (HfAlO) film, lanthanum aluminate (LaAlO) film and zirconium aluminate (ZrAlO) film.

10. The nonvolatile semiconductor memory device according to claim 1, wherein the second insulating film is an insulating film with a structure formed by laminating a plurality of films containing at least two of a silicon oxide, silicon nitride and hafnium oxide.

11. The nonvolatile semiconductor memory device according to claim 1, wherein the plurality of memory cells are serially connected to configure a NAND cell unit.

12. The nonvolatile semiconductor memory device according to claim 11, further comprising a first selection transistor connected to one end of the NAND cell unit and a second selection transistor connected to the other end of the NAND cell unit.

13. A nonvolatile semiconductor memory device comprising:
a memory cell array which has a plurality of data writable memory cells arranged therein, each memory cell having a floating gate electrode stacked on an element region surrounded by an element isolation region on a semiconductor substrate with a first insulating film disposed therebetween and a control gate electrode stacked on the floating gate electrode with a second insulating film disposed therebetween;
a row decoder which is connected to the memory cell array and selectively drives the control gate electrode when the memory cell is selected; and
a detrap pulse supply circuit which is connected to the row decoder and generates a detrap pulse signal after data is written into each of the plurality of memory cells, the row decoder causes the detrap pulse signal to the control gate electrode of the selected memory cell to extract charges from the second insulating film.

14. The nonvolatile semiconductor memory device according to claim 13, wherein the detrap pulse supply circuit supplies a pulse signal having pulse width in a range of 0.1 microsecond to 10 milliseconds to the control gate electrode as the detrap pulse signal.

15. The nonvolatile semiconductor memory device according to claim 13, wherein the detrap pulse supply circuit generates the detrap pulse signal having a voltage value which causes an electric field applied to the second insulating film to be set to 25 MV/cm at maximum.

16. The nonvolatile semiconductor memory device according to claim 13, wherein the detrap pulse supply circuit generates the detrap pulse signal after a verify write operation when a process of writing data into the memory cell is performed by the verify write operation.

17. The nonvolatile semiconductor memory device according to claim 16, wherein the detrap pulse supply circuit generates the detrap pulse signal having a polarity which causes electrons trapped in the second insulating film to be extracted from one of the control gate electrode and floating gate electrode.

18. A data write method for a data writable memory cell transistor having a floating gate electrode stacked on a semiconductor substrate with a first insulating film disposed therebetween and a control gate electrode stacked on the floating gate electrode with a second insulating film disposed therebetween, comprising:
supplying write voltage to the control gate electrode to write data into the memory cell;
reading out data from the memory cell into which data has been written and verifying a write state; and
supplying a detrap pulse signal to the control gate electrode to extract charges from the second insulating film after it is verified that a write process with respect to the memory cell has been performed.

19. The data write method according to claim 18, wherein a pulse signal having pulse width in a range of 0.1 microsecond to 10 milliseconds is supplied when the detrap pulse signal is supplied to the control gate electrode.

20. The data write method according to claim 18, wherein the detrap pulse signal having a voltage value which causes a maximum value of an electric field applied to the second insulating film to be set to 25 MV/cm is supplied when the detrap pulse signal is supplied to the control gate electrode.
